(19) United States
(12) Patent Application Publication
(10) Pub. No.: US 2016/0322387 A1
(43) Pub. Date: Nov. 3, 2016

(54) DISPLAY DEVICE AND MANUFACTURING METHOD THEREOF

(71) Applicant: SAMSUNG DISPLAY CO., LTD., Yongin-si (KR)

(72) Inventors: Dongil KIM, Suwon-si (KR); Joohyung LEE, Seongnam-si (KR)

(21) Appl. No.: 14/986,714

(22) Filed: Jan. 3, 2016

(30) Foreign Application Priority Data
Apr. 28, 2015 (KR) 10-2015-0059718

(51) Int. Cl. H01L 27/12; H01L 29/45; G02F 1/1362; H01L 29/66; G02F 1/1368; H01L 27/32; H01L 29/786

(52) U.S. Cl. CPC H01L 27/124; H01L 27/3276; H01L 29/45; H01L 29/78669; H01L 27/1259; H01L 29/66765; G02F 1/1368; G02F 1/136286; H01L 2227/323; G02F 2001/136295

(57) ABSTRACT

A display device includes: a first substrate; a gate line on the first substrate; a gate electrode disposed on the first substrate and protruding from the gate line; a gate insulating layer on the gate line and the gate electrode; a semiconductor layer on the gate insulating layer; and a source electrode and a drain electrode disposed on the semiconductor layer and spaced apart from each other. The gate electrode may include a first conductive layer on the first substrate, and the gate line may include the first conductive layer and a second conductive layer on the first conductive layer.

This application claims priority to Korean Patent Application No. 10-2015-0059718, filed on Apr. 28, 2015, and all the benefits accruing therefrom under 35 U.S.C. §119, the content of which in its entirety is herein incorporated by reference.

### BACKGROUND

1. Field

Embodiments of the invention relate to a display device having a thick wiring, and to a method of manufacturing the display device.

2. Description of the Related Art

Display devices are classified into liquid crystal display (“LCD”) devices, organic light emitting diode (“OLED”) display devices, plasma display panel (“PDP”) devices, electrophoretic display (“EPD”) devices, and the like, based on a light emitting scheme thereof.

An LCD device typically includes two substrates disposed to oppose each other, and a liquid crystal layer interposed between the two substrates.

A plurality of thin film transistors (“TFT”) and a pixel electrode are typically disposed on one of the two substrates of the LCD device, and a driving operation of a pixel electrode may be controlled by the TFT. The TFT may include a gate electrode, a semiconductor layer, at least a portion of which overlaps the gate electrode, and a source electrode and a drain electrode, which are spaced apart from each other on the semiconductor layer.

With the recent trend of display devices obtaining higher resolution, research has been conducted on a wiring constituting the TFT to reduce a width thereof but also increase a thickness thereof. However, the thicker wiring may lead to an open circuit due to a step difference at a point in which the wirings intersect one another.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY

Embodiments of the invention are directed to a display device efficiently reduced in formation of an open circuit of a wiring.

Further, Embodiments of the invention are directed to a display device including a gate line and a gate electrode which have different thicknesses, and to a semiconductor device including the same.

According to an exemplary embodiment of the invention, a display device includes: a first substrate; a gate line on the first substrate; a gate electrode disposed on the first substrate and protruding from the gate line; a gate insulating layer on the gate line and the gate electrode; a semiconductor layer on the gate insulating layer; and a source electrode and a drain electrode spaced apart from each other on the semiconductor layer. In such an embodiment, the gate electrode may include a first conductive layer on the first substrate, and the gate line may include the first conductive layer and a second conductive layer on the first conductive layer.

In an exemplary embodiment, the first conductive layer may include at least one of molybdenum (Mo), chromium (Cr), titanium (Ti), tantalum (Ta), aluminum (Al), silver (Ag), and copper (Cu).

In an exemplary embodiment, the second conductive layer may have a composition different from a composition of the first conductive layer, and include at least one of molybdenum (Mo), chromium (Cr), titanium (Ti), tantalum (Ta), aluminum (Al), silver (Ag), and copper (Cu).

In an exemplary embodiment, the first conductive layer may include at least one of molybdenum (Mo), chromium (Cr), titanium (Ti), and tantalum (Ta), and the second conductive layer may include at least one of aluminum (Al), silver (Ag), and copper (Cu).

In an exemplary embodiment, the first conductive layer may have a thickness in a range of about 50 nanometers (nm) to about 200 nm.

In an exemplary embodiment, the second conductive layer may have a thickness in a range of about 500 nm to about 1000 nm.

In an exemplary embodiment, the source electrode and the drain electrode each may include a third conductive layer on the semiconductor layer and a fourth conductive layer on the third conductive layer, the third conductive layer or the fourth conductive layer including at least one of molybdenum (Mo), chromium (Cr), titanium (Ti), tantalum (Ta), aluminum (Al), silver (Ag), and copper (Cu), respectively.

In an exemplary embodiment, the display device may further include: a second substrate opposing the first substrate; and a liquid crystal layer between the first substrate and the second substrate.

In an exemplary embodiment, the display device may further include: a first electrode disposed on the first substrate and connected to the drain electrode; a light emitting layer on the first electrode; and a second electrode on the light emitting layer.

According to another exemplary embodiment of the invention, a semiconductor device includes: a first substrate; a gate line on the first substrate; a gate electrode disposed on the first substrate and protruding from the gate line; gate insulating layer on the gate line and the gate electrode; a semiconductor layer on the gate insulating layer; and a source electrode and a drain electrode disposed on the semiconductor layer and spaced apart from each other. In such an embodiment, the gate electrode may include a first conductive layer on the first substrate, and the gate line may include the first conductive layer and a second conductive layer on the first conductive layer.

In an exemplary embodiment, the first conductive layer may include at least one of molybdenum (Mo), chromium (Cr), titanium (Ti), tantalum (Ta), aluminum (Al), silver (Ag), and copper (Cu).

In an exemplary embodiment, the second conductive layer may have a composition different from a composition of the first conductive layer, and include at least one of molybdenum (Mo), chromium (Cr), titanium (Ti), tantalum (Ta), aluminum (Al), silver (Ag), and copper (Cu).

In an exemplary embodiment, the first conductive layer may have a thickness in a range of about 50 nm to about 200 nm.

In an exemplary embodiment, the second conductive layer may have a thickness in a range of about 500 nm to about 1000 nm.

According to another exemplary embodiment of the invention, a method of manufacturing a display device includes: forming a first conductive layer by disposing a first conductive material on a first substrate; forming a second conductive layer by disposing a second conductive material on the first conductive layer; forming a gate electrode including the first conductive layer and a gate line including the first conductive layer and the second conductive layer by selectively etching the first conductive layer and the second conductive layer; providing a gate insulating layer on the gate line and the gate electrode; providing a semiconductor layer on the gate insulating layer; and providing a source electrode and a drain electrode spaced apart from each other on the semiconductor layer.

In an exemplary embodiment, the first conductive material may include at least one of molybdenum (Mo), chromium (Cr), titanium (Ti), tantalum (Ta), aluminum (Al), silver (Ag), and copper (Cu).

In an exemplary embodiment, the second conductive layer may have a composition different from a composition of the first conductive layer, and include at least one of molybdenum (Mo), chromium (Cr), titanium (Ti), tantalum (Ta), aluminum (Al), silver (Ag), and copper (Cu).

In an exemplary embodiment, the first conductive layer may have a thickness in a range of about 50 nm to about 200 nm.

In an exemplary embodiment, the second conductive layer may have a thickness in a range of about 500 nm to about 1000 nm.

According to exemplary embodiments of the invention described herein, a display device includes a gate line and a gate electrode having different thicknesses. In such embodiments, the thick gate line is provided to allow signals to be readily transmitted therethrough and the thin gate electrode is provided to effectively prevent an open circuit between a source electrode and a drain electrode across the gate electrode from occurring.

### BRIEF DESCRIPTION OF THE DRAWINGS

The above and other features of embodiments of the invention will be more clearly understood from the following detailed description taken in conjunction with the accompanying drawings, in which:

FIG. 1 is a plan view illustrating a display device according to an exemplary embodiment;

FIG. 2 is a cross-sectional view taken along line I-I′ of FIG. 1;

FIG. 3 is a cross-sectional view taken along line II-II′ of FIG. 1;

FIG. 4 is a plan view illustrating a display device according to an alternative exemplary embodiment;

FIGS. 5A through 5M are cross-sectional views illustrating a method of manufacturing a display device, according to an exemplary embodiment; and

FIG. 6 is a cross-sectional view illustrating a display device according to another alternative exemplary embodiment.

### DETAILED DESCRIPTION

Hereinafter, embodiments of the disclosure of invention will be described in more detail with reference to the accompanying drawings.

Although the invention can be modified in various manners and have several embodiments, specific embodiments are illustrated in the accompanying drawings and will be mainly described in the specification. However, the scope of the embodiments of the invention is not limited to the specific embodiments and should be construed as including all the changes, equivalents, and substitutions included in the spirit and scope of the invention.

In the drawings, certain elements or shapes may be simplified or exaggerated to better illustrate the invention, and other elements in an actual product may also be omitted. Like reference numerals refer to like elements throughout the specification. Thus, the drawings are intended to facilitate the understanding of the invention.

In addition, when a layer or element is referred to as being “on” another layer or element, the layer or element may be directly on the other layer or element, or one or more intervening layers or elements may be interposed therebetween.

The terminology used herein is for the purpose of describing particular embodiments only and is not intended to be limiting. Throughout the specification, when an element is referred to as being “connected” to another element, the element is “directly connected” to the other element, or “electrically connected” to the other element with one or more intervening elements interposed therebetween. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” can be termed likewise without departing from the teachings herein

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Some of the parts which are not associated with the description may not be provided in order to specifically describe embodiments of the invention, and like reference numerals refer to like elements throughout the specification.

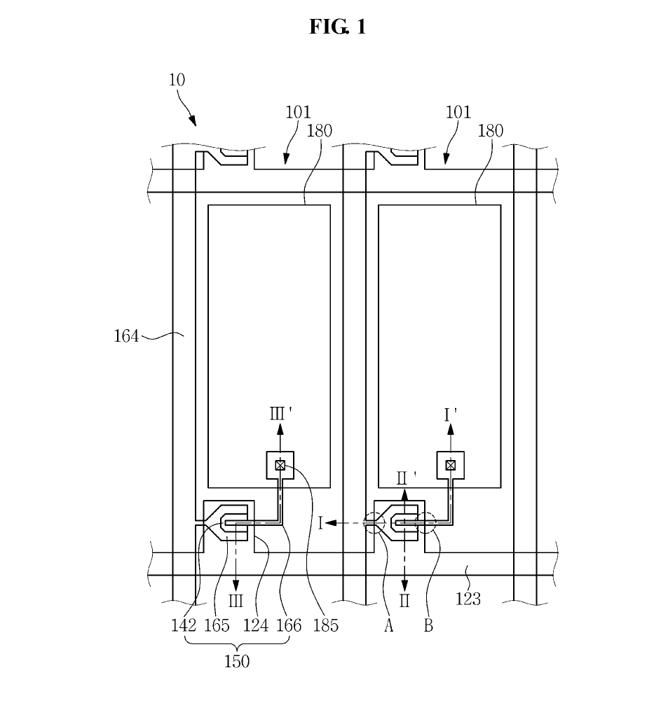

Hereinafter, an exemplary embodiment of the invention will be described with reference to FIGS. 1 through 3.

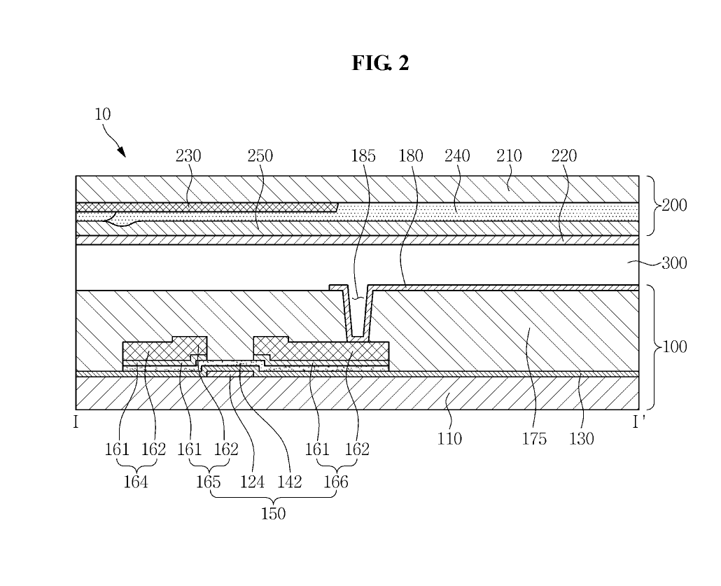

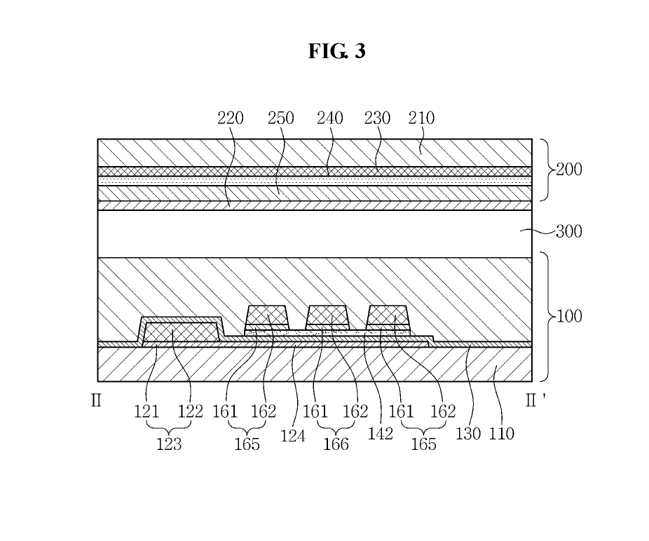

FIG. 1 is a plan view illustrating a display device according to an exemplary embodiment, FIG. 2 is a cross-sectional view taken along line I-I′ of FIG. 1, and FIG. 3 is a cross-sectional view taken along line II-II′ of FIG. 1.

An exemplary embodiment of the display device may be a liquid crystal display (“LCD”) device 10, but not being limited thereto. In one alternative exemplary embodiment, for example, the display device may be an organic light emitting diode (“OLED”) device. Hereinafter, for convenience of description, an exemplary embodiment where the display device is an LCD device will be described in detail.

The LCD device 10 may include a first substrate 110, a second substrate 210 disposed to oppose the first substrate 110, and a liquid crystal layer 300 interposed between the first substrate 110 and the second substrate 210.

In reference to FIGS. 1 through 3, the LCD device 10 may include a lower panel 100, an upper panel 200, and the liquid crystal layer 300 interposed between the lower panel 100 and the upper panel 200.

The lower panel 100 may include the first substrate 110, a thin film transistor (“TFT”) 150 on the first substrate 110, a planarization layer 175 on the TFT 150, and a first electrode 180 on the planarization layer 175.

The first substrate 110 may include an insulating substrate including or formed of a transparent material such as glass or plastic, for example.

Gate wirings 123 and 124 for transmitting a gate signal may be disposed on the first substrate 110. The gate wirings 123 and 124 may include a gate line 123 extending, for example, in a horizontal direction, and a gate electrode 124 protruding from the gate line 123 to define a protrusion. The gate electrode 124 may constitute the TFT 150, along with a source electrode 165, a drain electrode 166, and a semiconductor layer 142.

Although not illustrated, a storage wiring (not illustrated) that defines a storage capacitor, along with the first electrode 180, may further be disposed on the first substrate 110. The storage wiring includes a material substantially the same as that of the gate wirings 123 and 124, and may be disposed on a same layer the same as the gate wirings 123 and 124.

The gate wirings 123 and 124 each may include at least of aluminum (Al) or alloys thereof, silver (Ag) or alloys thereof, copper (Cu) or alloys thereof, and/or molybdenum (Mo) or alloys thereof, chromium (Cr), tantalum (Ta), and titanium (Ti), and/or the like.

In such an embodiment, the gate wirings 123 and 124 may have a multilayer structure including two conductive layers (not illustrated) having different physical properties from each other. In an exemplary embodiment, one of the two conductive layers may include a metal having low resistivity, for example, an aluminum (Al)-based metal, a silver (Ag)-based metal, or a copper (Cu)-based metal, such that a signal delay or a voltage drop of the gate wirings 123 and 124 may be reduced. In such an embodiment, the other one of the two conductive layers may include a material having a high contact property with transparent conductive oxide (“TCO”), such as indium tin oxide (“ITO”), indium zinc oxide (“IZO”), or aluminum zinc oxide (“AZO”). In one exemplary embodiment, for example, the material having a high contact property with TCO may include a molybdenum-based metal, chromium, titanium, tantalum, and the like.

In such an embodiment, as shown in FIG. 3, the gate electrode 124 may include a first conductive layer 121 on the first substrate 110, and the gate line 123 may include the first conductive layer 121 and a second conductive layer 122 on the first conductive layer 121.

The first conductive layer 121 may define the gate electrode 124, and the first conductive layer 121 of the gate line 123 may protrude to define the gate electrode 124. The second conductive layer 122 may be disposed only on the gate line 123.

In an exemplary embodiment, the first conductive layer 121 may include at least one of molybdenum (Mo), chromium (Cr), titanium (Ti), tantalum (Ta), aluminum (Al), silver (Ag), and copper (Cu), for example. In such an embodiment, the second conductive layer 122 may have composition different from that of the first conductive layer 121, and may include at least one of molybdenum (Mo), chromium (Cr), titanium (Ti), tantalum (Ta), aluminum (Al), silver (Ag), and copper (Cu), for example.

In one exemplary embodiment, for example, the first conductive layer 121 may be a layer including or formed of at least one of molybdenum (Mo), chromium (Cr), titanium (Ti), and tantalum (Ta), and the second conductive layer 122 may be a layer including or formed of at least one of aluminum (Al), silver (Ag), and copper (Cu).

In such an embodiment, the gate electrode 124 of the LCD device 10 may have a monolayer structure. In one exemplary embodiment, for example, the gate electrode 124 may be defined by the first conductive layer 121 including titanium (Ti).

In such an embodiment, the gate electrode 124 may have a thickness in a range of about 50 nanometers (nm) to about 200 nm. In such an embodiment, the gate electrode 124 is substantially thin, such that an open circuit of the wiring, which may occur due to a height difference (step difference) between a portion including the gate electrode 124 thereon and a portion absent the gate electrode 124, may be effectively prevented even when another wiring intersects the gate electrode 124.

In reference to FIG. 1, “A” denotes a portion of the source electrode 165 intersecting an end portion of the gate electrode 124, and “B” denotes a portion of the drain electrode 166 intersecting another end portion of the gate electrode 124.

When the display device has a high resolution, the source electrode 165 and the drain electrode 166 constituting the TFT 150 may have a small width. When the source electrode 165 and the drain electrode 166 having a small width are disposed to intersect the gate electrode 124, an open circuit of the source electrode 165 or the drain electrode 166 may occur at a boundary of the gate electrode 124 if the gate electrode 124 is substantially thick. In an exemplary embodiment, the gate electrode 124 is substantially thin, such that an open circuit, which may occur in the source electrode 165 or the drain electrode 166, is effectively prevented.

In an exemplary embodiment, the gate line 123 in the LCD device 10 may have a double-layer structure including the first conductive layer 121 and the second conductive layer 122. In one exemplary embodiment, for example, the first conductive layer 121 may have a thickness in a range of about 50 nm to about 200 nm, and the second conductive layer 122 may have a thickness in a range of about 500 nm to about 1000 nm.

In such an embodiment, the gate line 123 having a double-layer structure may have a thickness in a range of about 550 nm to about 1200 nm. In such an embodiment, the gate line 123 has a substantially thick thickness to allow signals to be effectively transmitted through the gate line 123.

In such an embodiment, since the source electrode 165 and the drain electrode 166 having a small width may not intersect the gate line 123, an open circuit, which may occur in the source electrode 165 and the drain electrode 166 due to the thickness of the gate line 123, may be effectively prevented.

The double-layer structure constituting the gate line 123 may include: a double-layer structure including a chromium (Cr) lower film and an aluminum (Al) upper film; a double-layer structure including an aluminum (Al) lower film and a molybdenum (Mo) upper film; and a double-layer structure including a titanium (Ti) lower film and a copper (Cu) upper film. In one exemplary embodiment, For example, the gate line 123 may include the first conductive layer 121 including or formed of titanium (Ti) and the second conductive layer 122 including or formed of copper (Cu).

However, the invention is not limited thereto, and the first conductive layer 121 and the second conductive layer 122 may include various types of metal and conductors.

A gate insulating layer 130 may be disposed on the first substrate 110 and the gate wirings 123 and 124. The gate insulating layer 130 may include silicon oxide (SiOₓ) or silicon nitride (SiNₓ). The gate insulating layer 130 may further include aluminum oxide, titanium oxide, tantalum oxide, or zirconium oxide.

A semiconductor layer 142, in which a channel of the TFT 150 is defined, may be disposed on the gate insulating layer 130. At least a portion of the semiconductor layer 142 may overlap the gate electrode 124. The semiconductor layer 142 may include or be formed of amorphous silicon (“a-Si”), crystalline silicon, or an oxide semiconductor including at least one of gallium (Ga), indium (In), tin (Sn), and zinc (Zn).

Although not illustrated, an ohmic contact layer may be disposed on the semiconductor layer 142. The ohmic contact layer may serve to enhance a contact property between the source electrode 165 and/or the drain electrode 166, which will be described later in greater detail, and the semiconductor layer 142. In one exemplary embodiment, for example, the ohmic contact layer may include or be formed of amorphous silicon doped with n-type impurities at high concentration (“n+a-Si”). In an exemplary embodiment, where the contact property between the source electrode 165 and/or the drain electrode 166 and the semiconductor layer 142 is sufficiently secured, the ohmic contact layer may be omitted.

Data wirings 164, 165 and 166 may be disposed on the semiconductor layer 142 and the gate insulating layer 130. The data wirings 164, 165 and 166 may include a data line 164 extending in a direction intersecting the gate line 123, for example, a vertical direction, the source electrode 165 branched out from the data line 164 to the semiconductor layer 142, and the drain electrode 166 spaced apart from the source electrode 165 and on the semiconductor layer 142 to oppose the source electrode 165 with respect to a channel region of the TFT 150. In such an embodiment, the drain electrode 166 may extend from an upper portion of the semiconductor layer 142 to a lower portion of the pixel electrode 180.

A pixel region 101 may be defined by the data line 164 and the gate line 123, but is not limited thereto. Alternatively, the pixel region 101 may be defined by a black matrix. The pixel region 101, for example, may include a red pixel region, a green pixel region, and a blue pixel region. However, such an exemplary embodiment is not limited thereto, and the pixel region 101 may further include a white pixel region.

The data wirings 164, 165 and 166 may have a monolayer structure or a multi-layer structure.

In an exemplary embodiment, the source electrode 165 and the drain electrode 166 may each include a third conductive layer 161 on the semiconductor layer 142 and a fourth conductive layer 162 on the third conductive layer 161. The third conductive layer 161 and the fourth conductive layer 162 may each include at least one of molybdenum (Mo), chromium (Cr), titanium (Ti), tantalum (Ta), aluminum (Al), silver (Ag), and copper (Cu), respectively.

The data line 164 may also include the third conductive layer 161 and the fourth conductive layer 162 on the third conductive layer 161. In one exemplary embodiment, for example, the third conductive layer 161 may include titanium (Ti) and the fourth conductive layer 162 may include copper (Cu).

A structure including the substrate 100 and the TFT 150 may be referred to as a semiconductor device. The semiconductor device may be also utilized in another electric or electronic device, aside from the display device. In such an embodiment, FIGS. 1 and 2 merely shows the structure of TFT 150 of one exemplary embodiment of a display device, and the structure of the TFT 150 of exemplary embodiments of the display device according to the invention is not limited to that shown in FIGS. 1 and 2.

In an exemplary embodiment, a planarization layer 175 may be disposed above the data wirings 164, 165 and 166, an exposed portion of the semiconductor layer 142, and an exposed portion of the gate insulating layer 130. Alternatively, an additional protection layer may be disposed above the data wirings 164, 165 and 166, an exposed portion of the semiconductor layer 142, and an exposed portion of the gate insulating layer 130, and the planarization layer 175 may be disposed on the protection layer.

The planarization layer 175 may have a monolayer or multi-layer structure including, for example, silicon oxide, silicon nitride, a photosensitive organic material, or a low dielectric constant insulating material such as a-Si:C:O or a-Si:O:F.

The planarization layer 175 may protect the TFT 150, and may planarize an upper portion of the TFT 150. The planarization layer 175 may have a thickness in a range of about 1.0 μm to about 2.5 μm.

A portion of the planarization layer 175 may be removed to thereby form a contact hole 185 through which the drain electrode 166 disposed below the first electrode 180 may be partially exposed.

The first electrode 180 may be disposed on the planarization layer 175 to be electrically connected to the drain electrode 166 through the contact hole 185. The first electrode 180 may include transparent conductive oxide, such as ITO, IZO, or AZO. According to an exemplary embodiment shown in FIGS. 1 to 3, the first electrode 180 may be a pixel electrode 180, and may be disposed in the pixel region 101.

Although not illustrated, a lower alignment layer may be disposed on the first electrode 180 and the planarization layer 175. The lower alignment layer may be a homeotropic layer and may include a photosensitive material. In one exemplary embodiment, for example, the lower alignment layer may include at least one material selected from: polyamic acid, polysiloxane, and polyimide.

The upper panel 200 may include the second substrate 210, a light shielding layer 230, a color filter 240, an overcoat layer 250, and a second electrode 220.

The second substrate 210 may include a transparent material including glass or plastic.

The light shielding layer 230 may be disposed on the second substrate 210. The light shielding layer 230 may be referred to as a black matrix, and may divide the plurality of color filters 240 from each other to define the pixel region.

Further, the light shielding layer 230 may prevent light supplied from a backlight unit (not illustrated) from being dissipated outwards therethrough, and prevent externally incident light from being irradiated on the gate line 123, the data line 164, and the TFT 150. The light shielding layer 230 may be disposed to overlap the gate line 123, the data line 164, and the TFT 150. In one exemplary embodiment, for example, the light shielding layer 230 may have a lattice structure disposed along the gate line 123 and the data line 164.

The color filter 240 may be disposed in the pixel region divided by the light shielding layer 230. The color filter 240 may include a red color filter, a green color filter, and a blue color filter. However, the types of the color filter 240 may not be limited thereto.

The red color filter, the green color filter, and the blue color filter may be disposed corresponding to the red pixel region, the green pixel region and the blue pixel region, respectively.

In one exemplary embodiment, for example, the color filter 240 may have a thickness in a range of about 2 μm to about 4 μm, but the thickness of the color filter 240 in exemplary embodiment may not be limited thereto.

The overcoat layer 250 may be disposed on the color filter 240. The overcoat layer 250 may planarize an upper portion of the color filter 240, and may protect the color filter 240. The overcoat layer 250 may include, for example, an acrylic epoxy-based material.

The second electrode 220 may be disposed on the overcoat layer 250. The second electrode 220 may be a common electrode.

The second electrode 220 may include transparent conductive oxide, such as ITO, IZO, or AZO.

Although not illustrated, the upper panel 200 may further include an upper alignment layer. The upper alignment layer may be disposed on the second electrode 220. The upper alignment layer may include a material substantially the same as that of the lower alignment layer.

A column spacer (not illustrated) may be disposed between the lower panel 100 and the upper panel 200. The column spacer may maintain a uniform interval between the lower panel 100 and the upper panel 200 to maintain a cell gap of the LCD device 10.

When surfaces of the first substrate 110 and the second substrate 210 facing each other therebetween, e.g., inner surfaces, are defined as upper surfaces of the first substrate 110 and the second substrate 210, respectively, and surfaces of the first substrate 110 and the second substrate 210 disposed opposite thereto, e.g., outer surfaces, are defined as lower surfaces of the first substrate 110 and the second substrate 210, respectively, polarizers (not illustrated) may further be disposed on the lower surface of the first substrate 110 and the lower surface of the second substrate 210, respectively.

The liquid crystal layer 300 may be disposed in a space between the lower panel 100 and the upper panel 200. The liquid crystal layer 300 may include liquid crystal molecules. The liquid crystal molecules of the liquid crystal layer 300 may have a structure in which a major or longitudinal axis thereof is disposed in a direction parallel to one of the lower panel 100 and the upper panel 200, and the direction is spirally twisted at an angle of about 90 degrees from a rubbing direction of the lower panel 100 to the upper panel 200. Alternatively, the liquid crystal layer 300 may include homeotropic liquid crystal molecules.

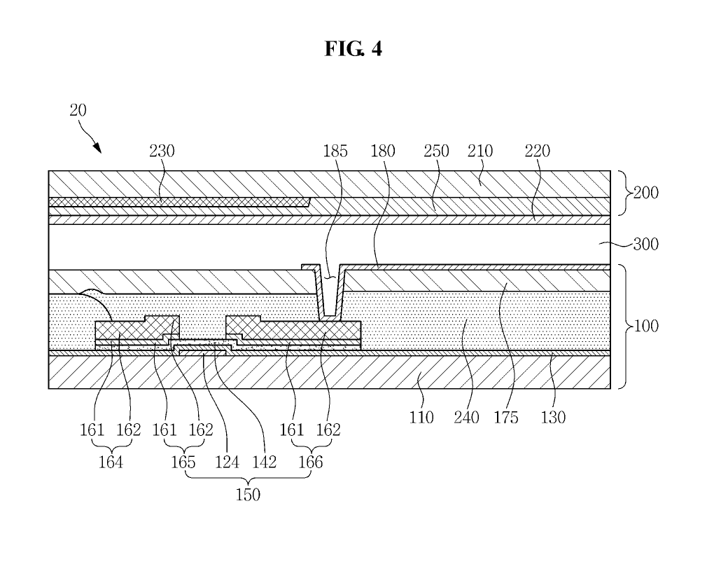

Hereinafter, an alternative exemplary embodiment will be described with reference to FIG. 4. FIG. 4 is a plan view illustrating a display device according to an alternative exemplary embodiment.

In such an embodiment, the display device may be an LCD device 20, and substantially the same as the LCD device 10 described above with reference to FIGS. 1 to 3 except that a color filter 240 is disposed in the lower panel 100. The same or like elements shown in FIG. 4 have been labeled with the same reference characters as used above to describe the exemplary embodiments of the LCD device 10 shown in FIGS. 1 to 3, and any repetitive detailed description thereof will hereinafter be omitted or simplified.

In reference to FIG. 4, a TFT 150 may be disposed on the first substrate 110, and the color filter 240 may be disposed on the TFT 150.

The color filter 240 may include a red color filter, a green color filter, and a blue color filter. The red color filter, the green color filter, and the blue color filter may be disposed corresponding to a red pixel region, a green pixel region and a blue pixel region, respectively.

A planarization layer 175 may be disposed on the color filter 240.

A contact hole 185 through which a drain electrode 166 disposed below a first electrode 180 may be partially exposed may be defined through the color filter 240 and the planarization layer 175. In an exemplary embodiment, a portion of the color filter 240 and a portion of the planarization layer 175 may be removed to thereby form the contact hole 185 through which a drain electrode 166 disposed below a first electrode 180 may be partially exposed. The first electrode 180 may be disposed on the planarization layer 175 to be electrically connected to the drain electrode 166 through the contact hole 185.

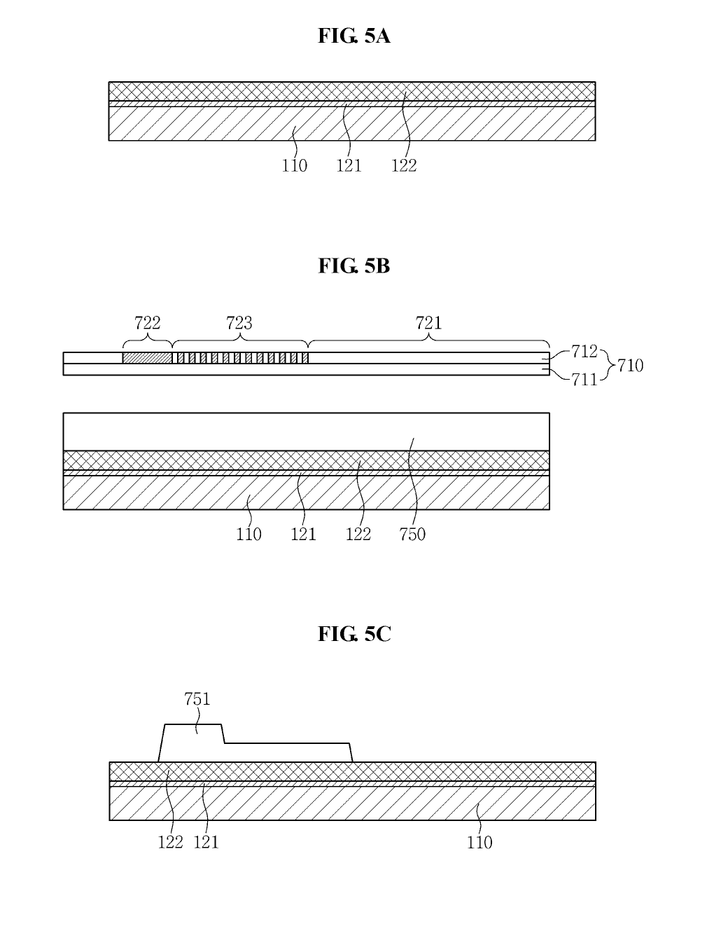

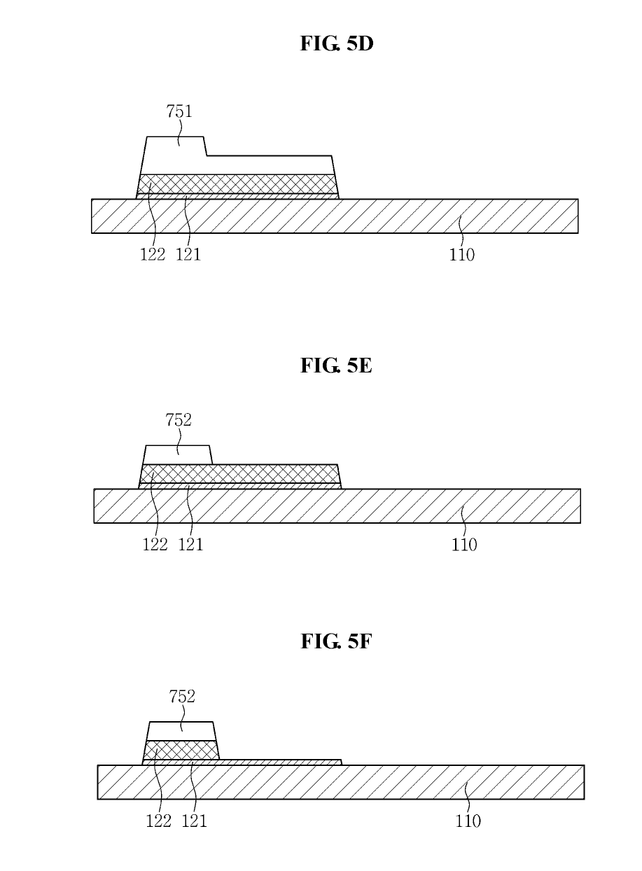

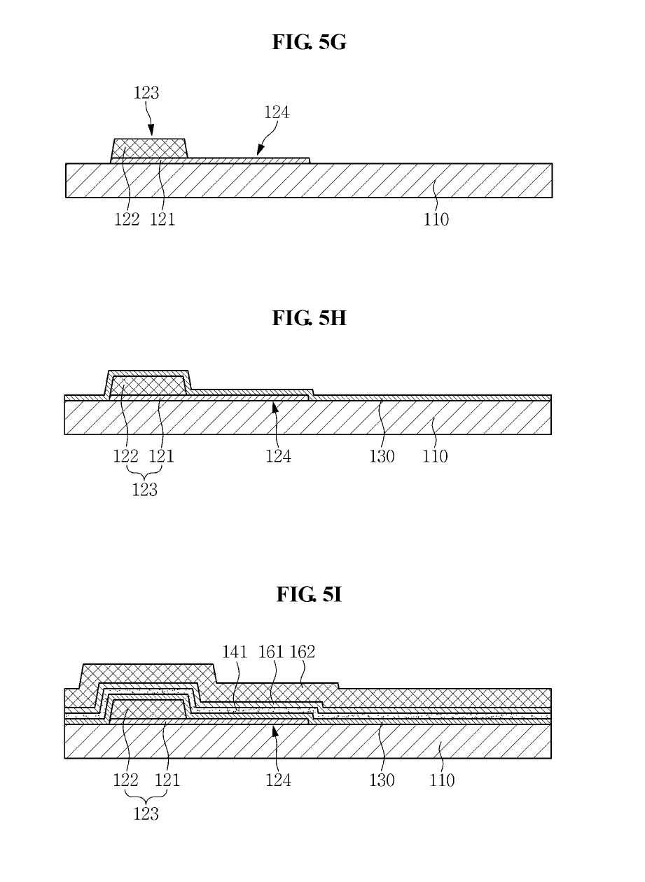

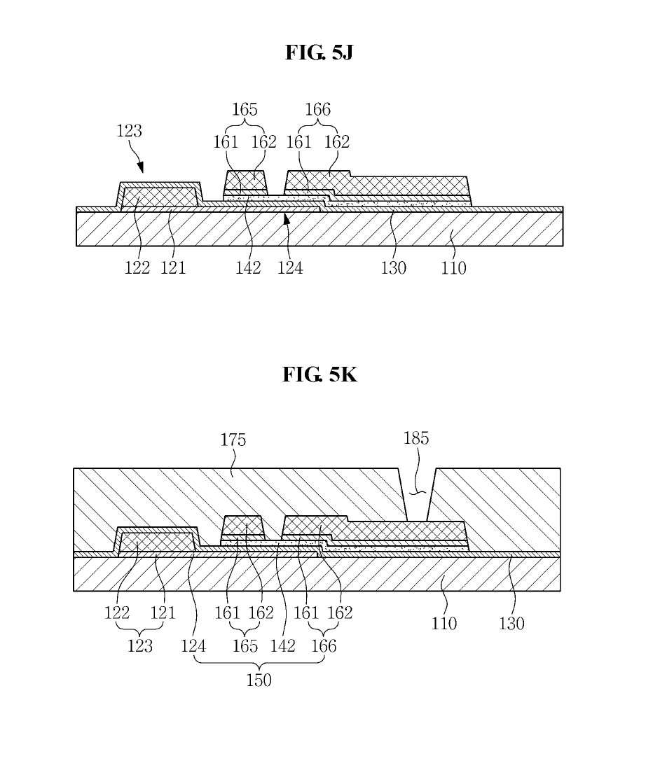

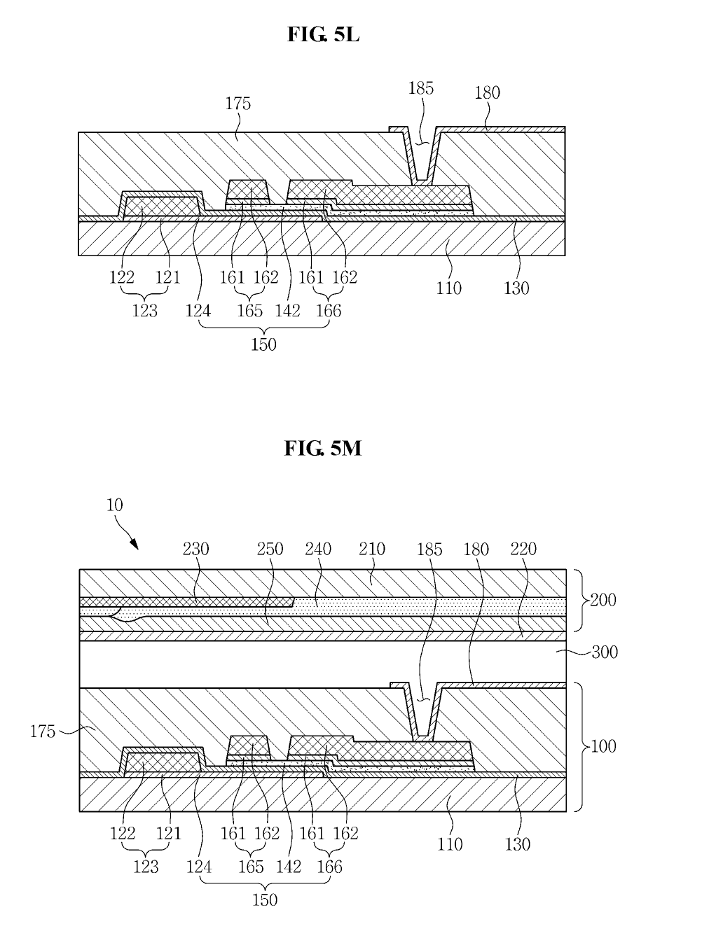

Hereinafter, an exemplary embodiment of a method of manufacturing a display device and a semiconductor device (refer to FIG. 5J) will be described with reference to FIGS. 5A through 5M.

FIGS. 5A through 5M are views illustrating processes of a method of manufacturing a display device, and more particularly, cross-sectional views corresponding to cross-sectional views taken along line of FIG. 1 with respect to the LCD device 10.

In reference to FIG. 5A, a first conductive layer 121 and a second conductive layer 122 may be disposed on a first substrate 110 including or formed of a transparent material such as glass or plastic.

The first conductive layer 121 may include at least one of molybdenum (Mo), chromium (Cr), titanium (Ti), tantalum (Ta), aluminum (Al), silver (Ag), and copper (Cu), and may have a thickness in a range of about 50 nm to about 200 nm.

The second conductive layer 122 may have composition different from that of the first conductive layer 121, and may include at least one of molybdenum (Mo), chromium (Cr), titanium (Ti), tantalum (Ta), aluminum (Al), silver (Ag), and copper (Cu), and may have a thickness in a range of about 500 nm to about 1000 nm.

In reference to FIG. 5B, a photoresist layer 750 may be provided on the second conductive layer 122, a first light exposure mask 710 may be disposed above the photoresist layer 750 while being spaced apart from the photoresist layer 750, and light may be irradiated thereon to perform selective light exposure on the photoresist 750.

In an exemplary embodiment, the photoresist layer 750 may employ any photoresist commonly used to form a metal pattern, and a positive-type photoresist having an etching property enhanced in accordance with light exposure may be used.

The first light exposure mask 710 may include a transparent glass substrate 711 and a light shielding pattern layer 712 above the transparent glass substrate 711. The light shielding pattern layer 712 may be formed by selectively disposing a light shielding material.

The first light exposure mask 710 may include a light transmission portion 721, a light shielding portion 722, and a semi-light transmission portion 723. The first light exposure mask 710 may be referred to as a half-tone mask.

The semi-light transmission portion 723 may have a structure in which a light transmission portion and a light shielding slit are alternately disposed. In such an embodiment, a level of light transmission of the semi-light transmission portion 723 may be adjusted based on an interval of the light transmission portion and the light shielding slit. In such an embodiment, the level of light transmission of the semi-light transmission portion 723 may be adjusted based on a concentration of a light shielding material.

The light shielding portion 722 of the first light exposure mask 710 may correspond to a portion in which a gate line 123 is provided, and the semi-light transmission portion 723 may correspond to a portion in which a gate electrode 124 is provided. The light transmission portion 721 may correspond to a portion, aside from a portion corresponding to the gate line 123 and a portion corresponding to the gate electrode 124.

In reference to FIG. 5C, a first patterning may be performed on the photoresist 750 having been subject to the selective light exposure, and thereby a first photoresist pattern 751 may be formed.

In reference to FIG. 5D, a first etching may be performed on the first conductive layer 121 and the second conductive layer 122 by a first etching process using the first photoresist pattern 751. Through the first etching, the first conductive layer 121 and the second conductive layer 122 may be removed in a portion aside from a portion of the gate line 123 and a portion of the gate electrode 124. Accordingly, a planar surface shape of the gate wirings 123 and 124 may be formed.

The first etching process may be a wet etching process or a dry etching process. A scheme of the etching may be suitably selected by those in the pertinent art.

In reference to FIG. 5E, a portion of the first photoresist pattern 751 may be removed, and thereby a second photoresist pattern 752 may be formed. Accordingly, a portion of the photoresist above the gate electrode 124 may all be removed, and thereby the second conductive layer 122 may partially be exposed.

In reference to FIG. 5F, the second conductive layer 122 may be selectively removed through a second etching process using the second photoresist pattern 752.

The second etching process may be a wet etching process or a dry etching process. By adjusting a ratio of the selective etching, the second conductive layer 122 may be selectively removed in a portion which is exposed without being protected by the second photoresist pattern 752.

In reference to FIG. 5G, the second photoresist pattern 752 on the second conductive layer 122 may be removed, and thereby the gate line 123 including the first conductive layer 121 and the second conductive layer 122 and the gate electrode 124 including the first conductive layer 121 may be formed.

In reference to FIG. 5H, a gate insulating layer 130 including or formed of silicon nitride (SiNₓ) or silicon oxide (SiOₓ) may be disposed on the gate line 123, the gate electrode 124, and an exposed portion of the first substrate 110. The gate insulating layer 130 may have a multi-layer structure including two or more insulating layers having different physical or chemical properties from each other.

In reference to FIG. 5I, a semiconductor material 141 may be disposed over an entire surface of the gate insulating layer 130, and a third conductive layer 161 and a fourth conductive layer 162 may be sequentially disposed.

The semiconductor material 141 may be a silicon-based semiconductor material such as amorphous silicon or polycrystalline silicon. In an exemplary embodiment, where the semiconductor material 141 illustrated in FIG. 5I is amorphous silicon, a laser beam may be irradiated on the semiconductor material 141, and thereby the amorphous silicon may be crystallized.

The semiconductor material 141 may include crystalline silicon and an oxide semiconductor material. The oxide semiconductor material may include at least one of zinc (Zn), gallium (Ga), indium (In), and tin (Sn).

Although not illustrated, an ohmic contact material may be disposed on the semiconductor material 141 to form an ohmic contact layer.

The third conductive layer 161 and the fourth conductive layer 162 may include or be formed of a conductive material for forming data wirings 164, 165, and 166. The third conductive layer 161 and the fourth conductive layer 162 may each include at least one of molybdenum (Mo), chromium (Cr), titanium (Ti), tantalum (Ta), aluminum (Al), silver (Ag), and copper (Cu), respectively.

In reference to FIG. 5J, a semiconductor layer 142, a data line 164, and a source electrode 165 may be formed through a selective etching process. In an exemplary embodiment, although not illustrated, a data line 164 may together be formed to constitute the data wirings 164, 165, and 166. In such an embodiment, selective light exposure may be performed using a second pattern mask.

The semiconductor layer 142 may at least partially overlap the gate electrode 124.

The data line 164 may intersect the gate line 123. The source electrode 165 may branch off from the data line 164 to extend on to the semiconductor layer 142, and the drain electrode 166 may be spaced apart from the source electrode 165 to be disposed above the semiconductor layer 142.

The gate electrode 124, the semiconductor layer 142, the source electrode 165 and the drain electrode 166 may constitute or collectively define a TFT 150. Accordingly, a semiconductor device may be manufactured as described above.

In reference to FIG. 5K, a planarization layer 175 may be disposed over an entire surface of a substrate including the TFT 150.

The planarization layer 175 may have a monolayer or multi-layer structure including, for example, silicon oxide, silicon nitride, a photosensitive organic material, or a low dielectric constant insulating material such as a-Si:C:O or a-Si:O:F. The planarization layer 175 may have a thickness in a range of about 1.0 μm to about 2.5 μm.

The planarization layer 175 may protect the TFT 150, and may planarize an upper portion of the TFT 150.

In reference to FIG. 5K, a portion of the planarization layer 175 may be removed, and thereby a contact hole 185 through which a portion of the drain electrode 166 is exposed may be formed. In an exemplary embodiment, light exposure and etching may be performed using a third pattern mask to form the contact hole 185.

In reference to FIG. 5L, a first electrode 180 electrically connected to the drain electrode 166 through the contact hole 185 may be formed on the planarization layer 175, and thereby a lower panel 100 may be manufactured.

The first electrode 180 may include or be formed of transparent conductive oxide, such as ITO, IZO, or AZO. In an exemplary embodiment, light exposure and etching may be performed using a fourth pattern mask to form the first electrode 180.

In reference to FIG. 5M, an upper panel 200 may be disposed above the lower panel 100 to oppose the lower panel 100, and a liquid crystal layer 300 may be disposed between the lower panel 100 and the upper panel 200, such that the LCD device 10 may be manufactured. The upper panel 200 may include a second substrate 210, a light shielding layer 230, a color filter 240, an overcoat layer 250, and a second electrode 220.

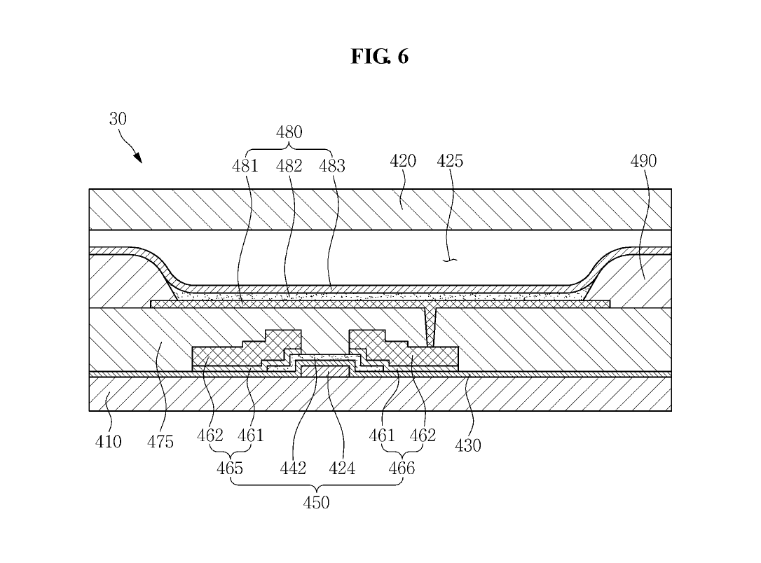

Hereinafter, another alternative exemplary embodiment of a display device will be described with reference to FIG. 6.

FIG. 6 is a cross-sectional view illustrating a display device according to another alternative exemplary embodiment. In such an embodiment, the display device may be an OLED display device 30.

In an exemplary embodiment, the OLED display device 30 may include a first substrate 410, a TFT 450, a planarization layer 475, and an OLED 480.

The first substrate 410 may include or be formed of an insulating material including glass, quartz, ceramic, and plastic. Alternatively, the first substrate 410 may include or be formed of a metal material, such as stainless steel.

Although not illustrated, a buffer layer may be disposed on the first substrate 410. The buffer layer may include at least one layer selected from various inorganic layers and organic layers. The buffer layer is configured to prevent infiltration of undesirable elements, such as moisture, into the TFT 450 or OLED 480, and to planarize a surface. In an alternative exemplary embodiment, the buffer layer may be omitted.

The TFT 450 may be disposed on the first substrate 410.

In an exemplary embodiment, a gate electrode 424 and a gate line (not illustrated) may be disposed on the first substrate 410.

The gate electrode 424 may be defined by a portion protruding from the gate line, and may include a first conductive layer. The gate line may include a first conductive layer and a second conductive layer disposed on the first conductive layer. The first conductive layer and the second conductive layer are substantially the same as those described above.

A gate insulating layer 430 may be disposed over an entire surface of the first substrate 410 including the gate electrode 424 and the gate line. A semiconductor layer 442 may be disposed on the gate insulating layer 430, and a source electrode 465 and a drain electrode 466 may be spaced apart from each other on the semiconductor layer 442.

The gate electrode 424, the semiconductor layer 442, the source electrode 465, and the drain electrode 466 constituting the TFT 450 are substantially the same as those described hereinabove, and any repetitive detailed description thereof will be omitted.

A planarization layer 475 may be disposed on the semiconductor layer 442, the source electrode 465, and the drain electrode 466.

The OLED 480 may be disposed on the planarization layer 475. The OLED 480 may include a first electrode 481, an organic light emitting layer 482 on the first electrode 481, and a second electrode 483 on the organic light emitting layer 482.

The first electrode 481 of the OLED 480 may be connected to the drain electrode 466 of the TFT 450 through a contact hole defined in the planarization layer 475.

Holes and electrons are injected from the first electrode 481 and the second electrode 483 into the organic light emitting layer 482, respectively. The holes and the electrons are combined with each other to form an exciton, and the OLED may emit light by energy generated when the exciton falls from an excited state to a ground state.

In such an embodiment, the first electrode 481 is a reflective electrode, and the second electrode 483 is a transflective electrode. Accordingly, light generated in the organic light emitting layer 482 may transmit the second electrode 483 to be emitted.

In such an embodiment, although not illustrated, at least one of a hole injection layer and a hole transporting layer may be further disposed between the first electrode 481 and the organic light emitting layer 482. In such an embodiment, at least one of an electron transporting layer and an electron injection layer may be further disposed between the organic light emitting layer 482 and the second electrode 483.

A pixel defining layer 490 may be disposed at an edge of the first electrode 481. The pixel defining layer 490 may have an aperture. The aperture of the pixel defining layer 490 may expose a portion of the first electrode 481. The second electrode 483 may be disposed not only on the organic light emitting layer 482 but also on the pixel defining layer 490. The OLED 480 may emit light from the organic light emitting layer 482 disposed in the aperture of the pixel defining layer 490. Accordingly, the pixel defining layer 490 may define a light emission region.

Although not illustrated, a capping layer may be disposed on the second electrode 483. The capping layer may protect the OLED 480.

In an exemplary embodiment, a second substrate 420 may be disposed on the OLED 480 to oppose the first substrate 410 to protect the OLED 480. The second substrate 420 may include or be formed of the same materials as that forming the first substrate 410.

An inert gas such as nitrogen gas (N₂) may be filled in a space 425 between the second electrode 483 and the second substrate 420

From the foregoing, it will be appreciated that various embodiments in accordance with the disclosure have been described herein for purposes of illustration, and that various modifications may be made without departing from the scope and spirit of the invention. Accordingly, the various exemplary embodiments disclosed herein are not intended to be limiting of the true scope and spirit of the invention. Various features of the above described and other exemplary embodiments can be mixed and matched in any manner, to produce further exemplary embodiments consistent with the invention.

What is claimed is:

1. A display device comprising:
a first substrate;
a gate line on the first substrate;
a gate electrode disposed on the first substrate and protruding from the gate line;
a gate insulating layer on the gate line and the gate electrode;
a semiconductor layer on the gate insulating layer;
a source electrode disposed on the semiconductor; and
a drain electrode disposed on the semiconductor layer and spaced apart from the source electrode,
wherein
the gate electrode comprises a first conductive layer on the first substrate, and
the gate line comprises the first conductive layer and a second conductive layer on the first conductive layer.

2. The display device of claim 1, wherein the first conductive layer comprises at least one of molybdenum (Mo), chromium (Cr), titanium (Ti), tantalum (Ta), aluminum (Al), silver (Ag), and copper (Cu).

3. The display device of claim 1, wherein
the second conductive layer has a composition different from a composition of the first conductive layer, and
the second conductive layer comprises at least one of molybdenum (Mo), chromium (Cr), titanium (Ti), tantalum (Ta), aluminum (Al), silver (Ag), and copper (Cu).

4. The display device of claim 1, wherein
the first conductive layer comprises at least one of molybdenum (Mo), chromium (Cr), titanium (Ti), and tantalum (Ta), and
the second conductive layer comprises at least one of aluminum (Al), silver (Ag), and copper (Cu).

5. The display device of claim 1, wherein the first conductive layer has a thickness in a range of about 50 nm to about 200 nm.

6. The display device of claim 1, wherein the second conductive layer has a thickness in a range of about 500 nm to about 1000 nm.

7. The display device of claim 1, wherein
the source electrode and the drain electrode each comprise:
a third conductive layer on the semiconductor layer; and
a fourth conductive layer on the third conductive layer,
wherein the third conductive layer or the fourth conductive layer comprise at least one of molybdenum (Mo), chromium (Cr), titanium (Ti), tantalum (Ta), aluminum (Al), silver (Ag), and copper (Cu), respectively.

8. The display device of claim 1, further comprising:
a second substrate opposing the first substrate; and
a liquid crystal layer between the first substrate and the second substrate.

9. The display device of claim 1, further comprising:
a first electrode disposed on the first substrate and connected to the drain electrode;
a light emitting layer on the first electrode; and
a second electrode on the light emitting layer.

10. A semiconductor device comprising:
a first substrate;
a gate line on the first substrate;
a gate electrode disposed on the first substrate and protruding from the gate line;
a gate insulating layer on the gate line and the gate electrode;
a semiconductor layer on the gate insulating layer;
a source electrode disposed on the semiconductor layer; and
a drain electrode disposed on the semiconductor layer and spaced apart from the source electrode,
wherein
the gate electrode comprises a first conductive layer on the first substrate, and
the gate line comprises the first conductive layer and a second conductive layer on the first conductive layer.

11. The semiconductor device of claim 10, wherein the first conductive layer comprises at least one of molybdenum (Mo), chromium (Cr), titanium (Ti), tantalum (Ta), aluminum (Al), silver (Ag), and copper (Cu).

12. The semiconductor device of claim 10, wherein
the second conductive layer has a composition different from a composition of the first conductive layer, and
the second conductive layer comprises at least one of molybdenum (Mo), chromium (Cr), titanium (Ti), tantalum (Ta), aluminum (Al), silver (Ag), and copper (Cu).

13. The semiconductor device of claim 10, wherein the first conductive layer has a thickness in a range of about 50 nm to about 200 nm.

14. The semiconductor device of claim 10, wherein the second conductive layer has a thickness in a range of about 500 nm to about 1000 nm.

15. A method of manufacturing a display device comprising:
forming a first conductive layer by disposing a first conductive material on a first substrate;
forming a second conductive layer by disposing a second conductive material on the first conductive layer;
forming a gate electrode comprising the first conductive layer and a gate line comprising the first conductive layer and the second conductive layer by selectively etching the first conductive layer and the second conductive layer;
providing a gate insulating layer on the gate line and the gate electrode;
providing a semiconductor layer on the gate insulating layer; and
providing a source electrode and a drain electrode, which are spaced apart from each other, on the semiconductor layer.

16. The method of claim 15, wherein the first conductive material comprises at least one of molybdenum (Mo), chromium (Cr), titanium (Ti), tantalum (Ta), aluminum (Al), silver (Ag), and copper (Cu).

17. The method of claim 15, wherein
the second conductive layer has a composition different from a composition of the first conductive layer, and
the second conductive layer comprises at least one of molybdenum (Mo), chromium (Cr), titanium (Ti), tantalum (Ta), aluminum (Al), silver (Ag), and copper (Cu).

18. The method of claim 15, wherein the first conductive layer has a thickness in a range of about 50 nm to about 200 nm.

19. The method of claim 15, wherein the second conductive layer has a thickness in a range of about 500 nm to about 1000 nm.
